(19) United States
(12) Patent Application Publication
(10) Pub. No.: US 2011/0244395 A1
(43) Pub. Date: Oct. 6, 2011

(54) APPARATUS AND METHOD FOR HAZE CONTROL IN A SEMICONDUCTOR PROCESS

(76) Inventors: Pei-Lin Huang, Taipei City (TW); Yi-Ming Wang, Taoyuan County (TW); Chun-Yen Huang, Taoyuan City (TW)

(21) Appl. No.: 12/754,613

(22) Filed: Apr. 6, 2010

(51) Int. Cl. G03F 7/20; G03B 27/42

(52) U.S. Cl. 430/319; 355/53

(57) ABSTRACT

A method for haze control in a semiconductor process, includes: providing an exposure tool with a photocatalyzer coating inside and exposing a wafer in the exposure tool in the presence of activation of the photocatalyzer coating. The photocatalyzer coating may be formed within an opaque region of a reticle.

### BACKGROUND OF THE INVENTION

1. Field of the Invention

The present invention relates generally to the field of semiconductor manufacturing processes and, more particularly, to an apparatus and a method for preventing haze growth during the manufacturing processes.

2. Description of the Prior Art

As semiconductor device manufacturers continue to produce smaller devices, the requirements for photomasks used in the fabrication of these devices continue to tighten. Photomasks, also known as reticles or masks, typically consist of substrates that have a pattern region formed on the substrate. As feature sizes of semiconductor devices decrease, the corresponding pattern on the reticle also become smaller and more complex. Consequently, the quality of the reticle has become one of the most crucial elements in establishing a robust and reliable semiconductor fabrication process.

However, during the fabricating process, haze grows on the reticle surface. These problems arise due to several factors, which include the use of shorter exposure wavelengths that produce highly energized photons as well as other environmental sources in a manufacturing facility. Some of hazes have been identified as cyanuric acid (C₃O₃N₃H₃) and ammonium sulfate ((NH₄)₂SO₄), but the true mechanisms for formation of haze may have multiple possible causes and still need further research.

The haze can alter the transmission properties of the substrate and/or cause defects on the wafer. If the transmission properties of a reticle are altered, the pattern from the reticle may not be accurately transferred to the wafer, thus causing defects or errors in the microelectronic devices formed on the wafer.

Therefore, it is desirable to limit these defects. One method of removing haze is by cleaning the reticle frequently before haze can influence the pattern transfer. However, the cost of cleaning the reticle having haze is very high. Moreover, if the reticle is cleaned often, the pattern on the reticle will be damaged. After several times of cleaning, the reticle can not be used anymore.

As a result, there is a need for an apparatus and a method for haze control in semiconductor processes which can elongate the life time of the reticle, and reduce the cleaning cost.

### SUMMARY OF THE INVENTION

In one aspect of the present invention, a method for haze control in a semiconductor process is provided. First, an exposure tool with a photocatalyzer coating inside is provided. Next, a wafer is exposed to ultraviolet (UV) light in the exposure tool. The UV light simultaneously activates the photocatalyzer coating to thereby eliminate unwanted substances in the chamber.

In another aspect of the present invention, an apparatus for haze control in a semiconductor process includes: a quartz-containing substrate, a circuit pattern region disposed on the quartz-containing substrate, and a photocatalyzer coating disposed on the quartz-containing substrate.

According to a preferred embodiment of the present invention, the photocatalyzer coating can be TiO₂, ZnO, SnO₂, ZrO₂, CdS, or ZnS.

The photocatalyzer coating in the present invention is to clean the chemical compounds causing haze and other unwanted chemical compounds in the chamber. For example, ammonia (NH₃), a reactant of forming haze, reacts with the photocatalyzer coating and be adsorbed on the photocatalyzer coating. Therefore, haze is prevented, and the reticle does not need to be cleaned frequently. As a result, the life time of the reticle is increased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts a method for haze control in a semiconductor process schematically.

FIG. 2 depicts a top view of an apparatus for haze control in a semiconductor process schematically according to a preferred embodiment of the present invention.

FIG. 3 depicts a top view of an apparatus for haze control in a semiconductor process schematically according to another preferred embodiment of the present invention.

FIG. 4 depicts a top view of an apparatus for haze control in a semiconductor process schematically according to another preferred embodiment of the present invention.

### DETAILED DESCRIPTION

As mentioned above, the formation of haze on a reticle may result in the formation of unwanted shadows or distortion of exposure radiation. Therefore, circuitry features that are to be formed on the substrate may be significantly compromised.

It has been found that formation of haze on a reticle may be as a result of various chemical reactions that may occur when ultraviolet radiation initiates photochemical reactions with gases of atmospheric air and/or environmental contaminants. The source of most haze generation can be traced back to chemical reactions involving NH₃.

Therefore, the method for haze control in a semiconductor process provided in the present invention primarily aims at removing NH₃ in the exposure tool during the exposure process. However, it should be understood that the photocatalyzer coating also clean other chemical compound such as H₂S, CO, acetaldehyde and styrene etc., inside the chamber of the exposure tool during the exposure process.

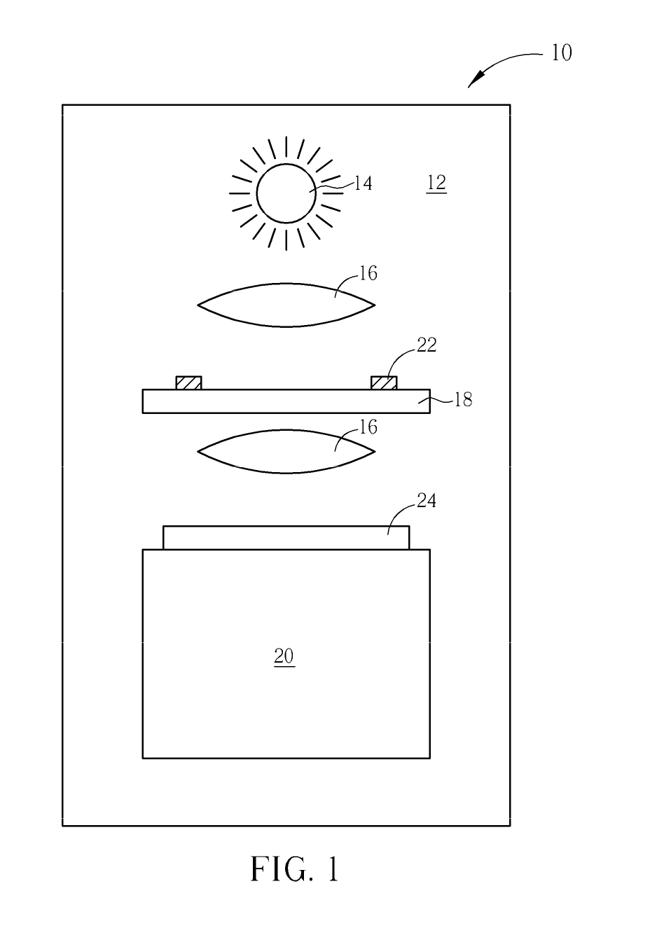

FIG. 1 depicts a method for haze control in a semiconductor process schematically.

As shown in FIG. 1, first, an exposure tool 10 with a chamber 12 is provided. The chamber 12 encompasses a light source 14, a projection lens 16, a reticle 18 and a wafer stage 20. The light source 14 in the exposure tool 10 can be ultraviolet light generally having a wavelength of less than 350 nm. Preferably, the light source 14 may be deep ultraviolet radiation having wavelengths between about 193 nm to about 204 nm. A photocatalyzer coating 22 is disposed inside the exposure tool 10. The photocatalyzer coating 22 may be disposed on the reticle 18, on a sidewall of the exposure tool 10, on the wafer stage 20 in the exposure tool 10 or any region where will be irradiated by the light source 14 during the exposure process. Then, a wafer 24 is sent into the exposure tool 10. Next, the light source 10 emanates UV light to form a light path from the projection lens 16 through the wafer 24 and exposing the wafer 10 to the UV light. At the same time, the photocatalyzer coating 22 is irradiated as well. Therefore, the photocatalyzer coating 22 is activated by the light source 10 during the exposure of the wafer 24.

The photocatalyzer coating 22 may include but not limited to TiO₂, ZnO, SnO₂, ZrO₂, CdS or ZnS, preferably TiO₂ with anatase phase. When the photocatalyzer coating 22 is irradiated by the light source 14 in the exposure tool 10, electron holes with positive charges are generated in the valence band of the photocatalyzer coating 22. These electron holes may oxidize the water in the environment and produce hydroxyl radicals. Finally, the NH₃ inside the chamber 12 will react with the hydroxyl radicals to form chemicals such as NO₃⁻, which can be adsorbed by the photocatalyzer coating 22. As a result, haze will not form because substantially all ammonia (NH₃) molecules in the chamber are eliminated. During the activation of the photocatalyzer coating 22, other unwanted chemical compound inside the chamber 12 may be adsorbed by the photocatalyzer coating 22 as well. After a period of time, the photocatalyzer coating 22 can be washed to remove the adsorbed chemicals.

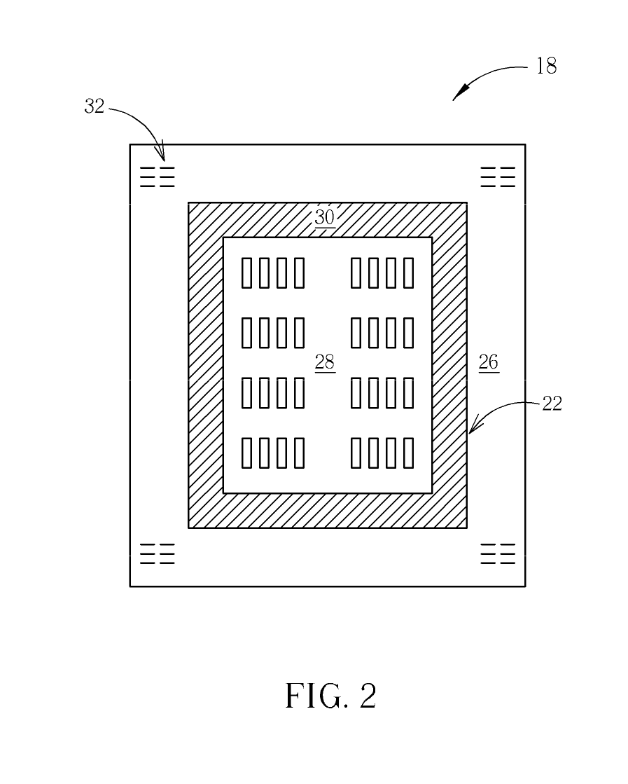

FIG. 2 schematically depicts a top view of an apparatus for haze control in a semiconductor process. As shown in FIG. 2, a reticle 18 for haze control include a quartz-containing substrate 26, a circuit pattern region 28 disposed on the quartz-containing substrate 26, an opaque region 30 surrounding the circuit pattern region 28, a reticle alignment mark 32 disposed near an edge of the reticle 18. The reticle alignment mark 32 is for aligning the reticle 18 to a precise position in the exposure tool 10. According to a preferred embodiment of the present invention, the photocatalyzer coating 22 is disposed within the opaque region 30 of the reticle 18. For example, the photocatalyzer coating 22 can be totally overlapped with the opaque region 30 and completely covers the entire opaque region 30.

As set forth in FIGS. 1 and 2, generally, the exposure tool 10 is in a step-and-scan manner. That is, a projection exposure method that exposes a pattern on a reticle 18 onto a wafer 24 by continuously scanning the wafer 24 relative to the reticle 18, and by moving, after a shot of exposure, the wafer 24 stepwise to the next exposure area to be shot. The opaque region 30 on the reticle 18 is for limiting light source 14 to irradiate on the present exposure area. Therefore, the opaque region 30 is designed to be opaque and prevent light source 14 from penetration. Moreover, during the exposure process, the light source 14 may irradiate on entire pattern region 28 and on a part of the opaque region 30 to guarantee the pattern region 28 is totally irradiated in the present shot. Therefore, the photocatalyzer coating 22 on the opaque region 30 will be activated during the exposure process. As a result, unwanted chemical compounds such as NH₃ in the chamber 12 of the exposure tool 10 will be cleaned by the photocatalyzer coating 22. The haze is thus prevented.

Furthermore, since the photocatalyzer coating 22 can be disposed on the opaque region 30, the photocatalyzer coating 22 can be easily integrated with the conventional reticle 18.

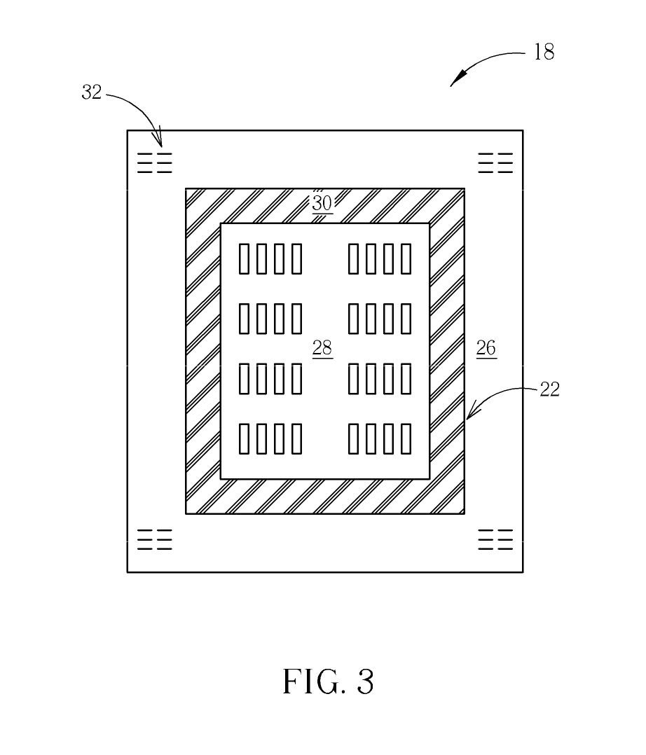

FIG. 3 depicts a top view of an apparatus for haze control in a semiconductor process schematically according to another preferred embodiment of the present invention, wherein like numerals designate like components in the drawing. As shown in FIG. 3, the photocatalyzer coating 22 can be disposed on the opaque region 30 in a stripe-like manner. However, other patterns of the photocatalyzer coating 22 can be employed, such as in dotted-like manner, as long as the photocatalyzer coating 22 can be irradiated by the light source 14 properly.

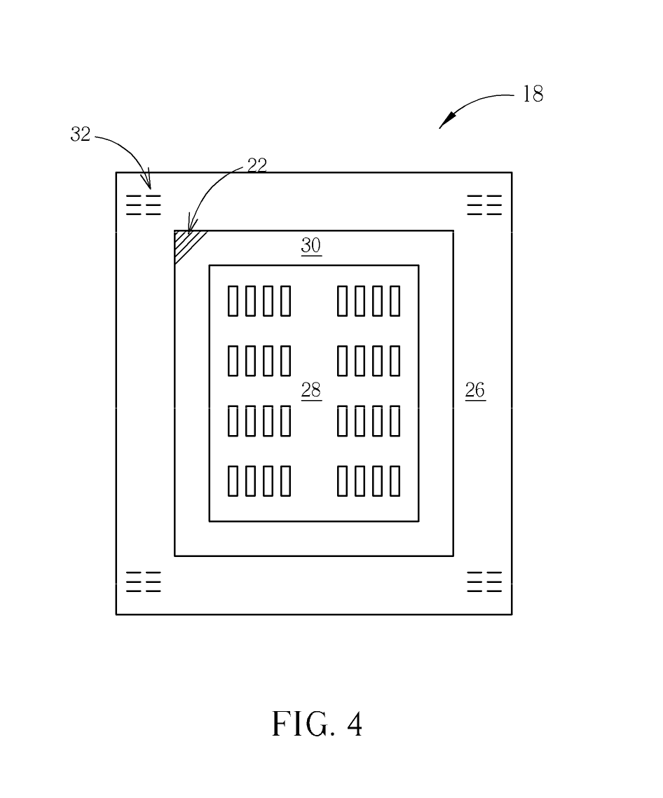

FIG. 4 depicts a top view of an apparatus for haze control in a semiconductor process schematically according to another preferred embodiment of the present invention, wherein like numerals designate like components in the drawing.

It should be noted that the photocatalyzer coating 22 can be disposed on anywhere of the opaque region 30, and the photocatalyzer coating 22 is not limited to be totally overlapped with the opaque region 30. For example, as shown in FIG. 4, the photocatalyzer coating 22 can be positioned merely at one edge of the opaque region 30. Based on different requirements, the photocatalyzer coating 22 may be located at anywhere of the opaque region 30, as long as the light source 10 can illuminate and activate the photocatalyzer coating 22.

Because the unwanted chemical compounds inside the chamber are cleaned and adsorbed by the photocatalyzer coating, the haze will not be formed on the reticle during the exposure process. Therefore, the circuit pattern region does not need to be cleaned due to haze, and life time of reticle is extended. Besides, although the photocatalyzer coating on the reticle needs to be cleaned after a period of the time, however, the cost of cleaning the photocatalyzer coating is much lower than the cost of cleaning the haze on the circuit pattern region.

Those skilled in the art will readily observe that numerous modifications and alterations of the device and method may be made while retaining the teachings of the invention.

What is claimed is:

1. A method for haze control in a semiconductor process, comprising:
providing an exposure tool with a photocatalyzer coating inside; and
exposing a wafer in the exposure tool in the presence of activation of the photocatalyzer coating.

2. The method for haze control in a semiconductor process of claim 1, wherein the exposure tool comprises a reticle, and the photocatalyzer coating is coated on the reticle.

3. The method for haze control in a semiconductor process of claim 2, wherein the reticle comprises:
a quartz-containing substrate;
a circuit pattern region disposed on the quartz-containing substrate; and
an opaque region surrounding the circuit pattern region, wherein the photocatalyzer coating is disposed within the opaque region.

4. The method for haze control in a semiconductor process of claim 3, wherein the photocatalyzer coating completely covers the opaque region.

5. The method for haze control in a semiconductor process of claim 3, wherein the reticle further comprises a reticle alignment mark near an edge of the reticle.

6. The method for haze control in a semiconductor process of claim 1, wherein the photocatalyzer coating is made of material selected from the group consisting of TiO₂, ZnO, SnO₂, ZrO₂, CdS, and ZnS.

7. An apparatus for haze control in a semiconductor process, comprising:
a substrate;
a circuit pattern region disposed on the substrate; and
a photocatalyzer coating disposed on the substrate.

8. The apparatus for haze control in a semiconductor process of claim 7 further comprising an opaque region surrounding the circuit pattern region, wherein the photocatalyzer coating is disposed within the opaque region.

9. The apparatus for haze control in a semiconductor process of claim 8, wherein the photocatalyzer coating completely covers the opaque region.

10. The apparatus for haze control in a semiconductor process of claim 7 further comprising a reticle alignment mark disposed near an edge of the substrate.

11. The apparatus for haze control in a semiconductor process of claim 7, wherein the photocatalyzer coating is made of material selected from the group consisting of TiO₂, ZnO, SnO₂, ZrO₂, CdS, and ZnS.

12. The apparatus for haze control in a semiconductor process of claim 7, wherein the photocatalyzer coating is made of TiO₂ with anatase phase.
